(19) United States
(12) Patent Application Publication
(10) Pub. No.: US 2025/0359067 A1
(43) Pub. Date: Nov. 20, 2025

(54) MANAGING SLIT STRUCTURES IN SEMICONDUCTOR DEVICES

(71) Applicant: Yangtze Memory Technologies Co., Ltd., Wuhan (CN)

(72) Inventors: Changzhi SUN, Wuhan (CN); Yuancheng YANG, Wuhan (CN); Dongxue ZHAO, Wuhan (CN); Kun ZHANG, Wuhan (CN); Wenxi ZHOU, Wuhan (CN)

(21) Appl. No.: 18/783,366

(22) Filed: Jul. 24, 2024

Related U.S. Application Data
(63) Continuation of application No. PCT/CN2024/093303, filed on May 15, 2024.

(51) Int. Cl. H10B 53/20; H01L 21/28; H01L 23/528; H01L 29/51; H01L 29/78; H10B 51/10; H10B 51/20; H10B 53/10

(52) U.S. Cl. CPC H10B 53/20; H01L 23/5283; H10B 51/10; H10B 51/20; H10B 53/10; H10D 30/701; H10D 64/033; H10D 64/689

(57) ABSTRACT

Systems, devices, and methods for managing slit structures in a semiconductor device are provided. In one aspect, a semiconductor device includes a first stack structure having interleaved first conductive layers and first dielectric layers, and a capacitor structure extending through the first stack structure along a first direction. The capacitor structure includes an inner electrode layer, a ferroelectric layer and a plurality of outer electrodes. Adjacent outer electrodes are arranged and isolated from each other along the first direction. The semiconductor device includes a slit structure. A portion of the slit structure extends partially into the first stack structure along a second direction perpendicular to the first direction. The semiconductor device includes a second stack structure adjacent to the first stack structure. The second stack structure includes the first conductive layers interleaved with second dielectric layers.

### CROSS-REFERENCE TO RELATED APPLICATIONS

This application is a continuation of International Application No. PCT/CN2024/093303, filed on May 15, 2024, the disclosure of which is hereby incorporated by reference in its entirety.

### TECHNICAL FIELD

The present disclosure relates to semiconductor devices and fabrication processes for semiconductor devices.

### BACKGROUND

Semiconductor memory devices may be classified into non-volatile memory devices, such as flash memory devices, and volatile memory devices. The semiconductor memory devices can have different structures with different densities of memory cells and lines on a chip. A memory device normally includes a memory block of memory cells and control circuitries. The control circuitries can facilitate operations of the memory block.

### SUMMARY

The present disclosure describes methods, devices, systems and techniques for managing slit structures in three-dimensional (3D) memory devices.

One aspect of the present disclosure features a semiconductor device, including a first stack structure, which includes interleaved first conductive layers and first dielectric layers, and a capacitor structure extending through the first stack structure along a first direction. The capacitor structure includes an inner electrode layer, a ferroelectric layer and a plurality of outer electrodes. Adjacent outer electrodes of the plurality of outer electrodes are arranged and isolated from each other along the first direction. The semiconductor device includes a slit structure. A portion of the slit structure extends partially into the first stack structure along a second direction perpendicular to the first direction. The semiconductor device includes a second stack structure adjacent to the first stack structure. The second stack structure and the first stack structure are arranged along the second direction or a third direction perpendicular to the first direction and the second direction. The second stack structure includes the first conductive layers interleaved with second dielectric layers.

In some implementations, the semiconductor device includes a first transistor coupled to a first end of the capacitor structure, and a second transistor coupled to a second end of the capacitor structure.

In some implementations, the first transistor includes a gate structure extending along the first direction and a channel layer laterally surrounding the gate structure. The gate structure is coupled to the inner electrode layer of the capacitor structure. A first end of the channel layer is coupled to a select gate layer, and a second end of the channel layer is coupled to a first bit line. The second transistor includes a channel structure extending along the first direction. A first end of the channel structure being coupled to the inner electrode layer of the capacitor structure, and a second end of the channel structure is coupled to a second bit line.

In some implementations, the semiconductor device includes conductive structures extending into the second stack structure at different depths and each conductive structure is connected to a respective one of the first conductive layers.

In some implementations, each of the first conductive layers includes doped polysilicon in contact with a corresponding one of the outer electrodes of the capacitor structure.

In some implementations, the semiconductor device includes a plurality of memory arrays each having the first stack structure, the capacitor structure, the portion of the slit structure and the second stack structure.

In some implementations, the portion of the slit structure is an inner portion of the slit structure. The slit structure further includes an outer portion configured to isolate adjacent memory arrays of the plurality of memory arrays.

In some implementations, the semiconductor device includes a first region, a second region, and a third region arranged along the second direction. The first stack structure is located in the first region and the third region. The second stack structure is located in the second region.

In some implementations, the second region includes an edge area and a center area. The second stack structure is at the center area, and the first stack structure extends into the edge area of the second region.

In some implementations, the portion of the slit structure includes one or more liner slit fingers.

In some implementations, the first dielectric layers include air gaps surrounded by silicon oxide, and the second dielectric layers include silicon oxide.

Another aspect of the present disclosure features a semiconductor device including a first stack structure including interleaved first conductive layers and first dielectric layers and a second stack structure laterally surrounded by the first stack structure. The second stack structure includes the first conductive layers interleaved with second dielectric layers. The semiconductor device includes a plurality of conductive structures extending into the second stack structure at different depths along a first direction. Each of the plurality of conductive structures is connected to a respective one of the first conductive layers.

In some implementations, the first dielectric layers include air gaps.

In some implementations, the plurality of conductive structures includes a conductive material surrounded by spacers.

In some implementations, the semiconductor device further includes a capacitor structure extending through the first stack structure along the first direction. The capacitor structure includes an inner electrode layer, a ferroelectric layer and a plurality of outer electrodes. Adjacent outer electrodes of the plurality of outer electrodes are arranged and isolated from each other along the first direction.

In some implementations, each of the first conductive layers includes doped polysilicon and is in contact with a corresponding one of the outer electrodes of the capacitor structure.

Another aspect of the present disclosure features a method including: forming a first stack structure including interleaved first conductive layers and first dielectric layers; forming a capacitor structure extending through the first stack structure along a first direction and including an inner electrode layer, a ferroelectric layer and a plurality of outer electrodes. Adjacent outer electrodes of the plurality of outer electrodes are arranged and isolated from each other along the first direction. The method includes forming a slit structure, where a portion of the slit structure extends partially into the first stack structure; and forming a second stack structure including the first conductive layers interleaved with second dielectric layers. The second stack structure is adjacent to the first stack structure.

In some implementations, forming the second stack structure includes: forming the inner electrode layer, the ferroelectric layer and an outer electrode layer in capacitor holes; forming a stack structure including the first conductive layers interleaved with the second dielectric layers; forming a slit structure trench extending through the stack structure along the first direction; and etching a part of the second dielectric layers through the slit structure trench to form openings and expose a part of the outer electrode layer.

In some implementations, forming the first stack structure includes: etching the exposed part of the outer electrode layer to form the plurality of outer electrodes; and at least partially filling the openings with a dielectric material to form the first dielectric layers.

In some implementations, the method includes forming conductive structures extending into the second stack structure at different depths. Each of the conductive structures is electronically connected to a respective one of the first conductive layers.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a top-down view of an example semiconductor device.

FIG. 1B illustrates an enlarged top-down view of a first implementation of a slit structure in a sub memory array tile (sub-MAT) of the semiconductor device of FIG. 1A.

FIG. 2A illustrates a cross-section view of an example first stack structure along the axis A-A′ of FIG. 1B.

FIG. 2B illustrates a schematic view of an example 2TXC structure.

FIG. 2C illustrates a cross-section view of a second stack structure along B-B′ axis of FIG. 1B.

FIGS. 3A-3C illustrates additional implementations of the slit structure in a sub-MAT of the example semiconductor device of FIG. 1A.

FIGS. 4A-4E illustrate cross-section views of the semiconductor device along the A-A′ axis of the FIG. 1B at various stages of a fabrication process.

FIG. 5 is a flow diagram of an example process to form the semiconductor device.

FIG. 6 illustrates a block diagram of a system.

It is to be understood that the various exemplary implementations shown in the figures are merely illustrative representations and are not necessarily drawn to scale.

### DETAILED DESCRIPTION

Ferroelectric Random Access Memory (FeRAM) is a high performance and low-power non-volatile memory that can combine the benefits of conventional non-volatile memories (e.g., Flash and EEPROM) and high-speed RAM (e.g., SRAM and DRAM). FeRAM can outperform existing memories like EEPROM and Flash with less power consumption, faster response, and greater endurance to multiple read-and-write operations. There are two types of FeRAMs in general: the capacitor type and the field-effect transistor (FET) type. A capacitor-type FeRAM cell includes at least one ferroelectric capacitor and at least one MOSFET used for cell selection. The capacitor-type FeRAM cell can also be referred to as an nTnC FeRAM memory cell. A FET-type FeRAM cell is capacitor-free and includes a single ferroelectric-gate FET (FeFET).

Implementations of the present disclosure provide devices and methods to form such semiconductor devices. In some implementations, the semiconductor device includes a first stack structure having interleaved first conductive layers and first dielectric layers, and a capacitor structure extending through the first stack structure along a first direction. The capacitor structure includes an inner electrode layer, a ferroelectric layer and a plurality of outer electrodes. Adjacent outer electrodes of the plurality of outer electrodes are arranged and isolated from each other along the first direction. The semiconductor device includes a slit structure. A portion of the slit structure extends partially into the first stack structure along a second direction perpendicular to the first direction. The semiconductor device includes a second stack structure adjacent to the first stack structure. The second stack structure and the first stack structure are arranged along the second direction or a third direction perpendicular to the first direction and the second direction. The second stack structure includes the first conductive layers interleaved with second dielectric layers.

Implementations of the present disclosure can provide one or more of the following technical advantages and/or benefits. The inner portion of the slit structure trenches can increase the contact area between etchants and the sacrificial layers (also referred to as second dielectric layers in this disclosure) of a stack structure deeper into the memory array (also called sub-MAT in this disclosure) along lateral directions parallel to the substrate surface, enhancing uniformity of the etching process within the sub-MAT. Increased contact area can also reduce the etching duration, which can improve the efficiency of the etching process. In addition, some portions of the sacrificial layers can be retained in certain areas of the sub-MAT for plate lines pad-out by controlling the etching process. This eases the need for extra process steps to separate the memory region and the pad-out region in a sub-MAT, hence enhances integration of the system.

Moreover, for a multi-layer stacked ferroelectric capacitors, the oxidant may oxidize the surface of the heavily doped polysilicon, if only heavily doped polysilicon is used as the outer electrode during the deposition process of the hafnium-based ferroelectric thin film. Because the dielectric constant of this silicon dioxide layer is much lower than that of the ferroelectric layer, by forming a silicon dioxide layer at the polysilicon/ferroelectric interface, the actual voltage across the ferroelectric layer can be lower than the applied voltage. Additionally, the defect states in this oxide layer may capture electrons, which hinders the flipping of ferroelectric domains. The techniques described in this disclosure can enable disposition of a metal layer (e.g., outer electrodes) on the polysilicon sidewalls before depositing the hafnium-based ferroelectric thin film to improve the memory cell performance.

Moreover, a 2TXC structure can be implemented in the semiconductor device. The 2TXC can refer to a structure with two transistors (2T) and one or more capacitors (XC). The 2TXC structure includes a first transistor with channel all around configuration and a second transistor with gate all around configuration. The first transistor is deployed for read operations, and the second transistor is deployed for write operations. The implementation of the 2TXC structure can enable non-destructive read operations without the need for rewrite operations.

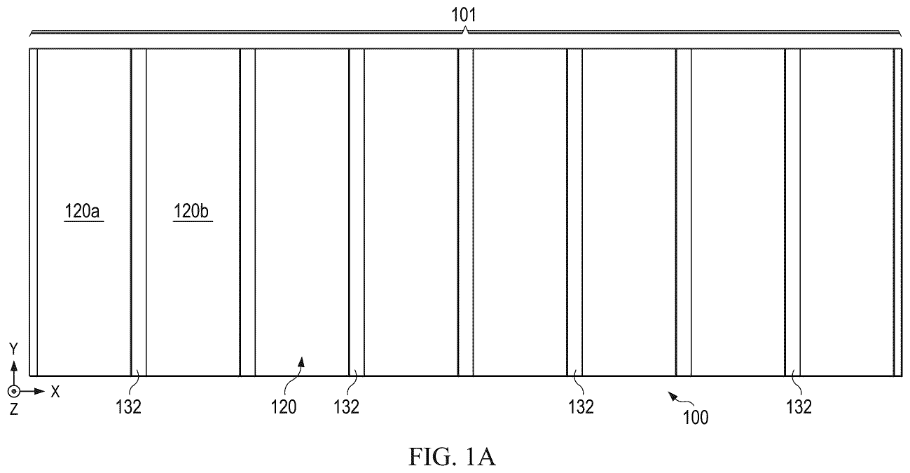

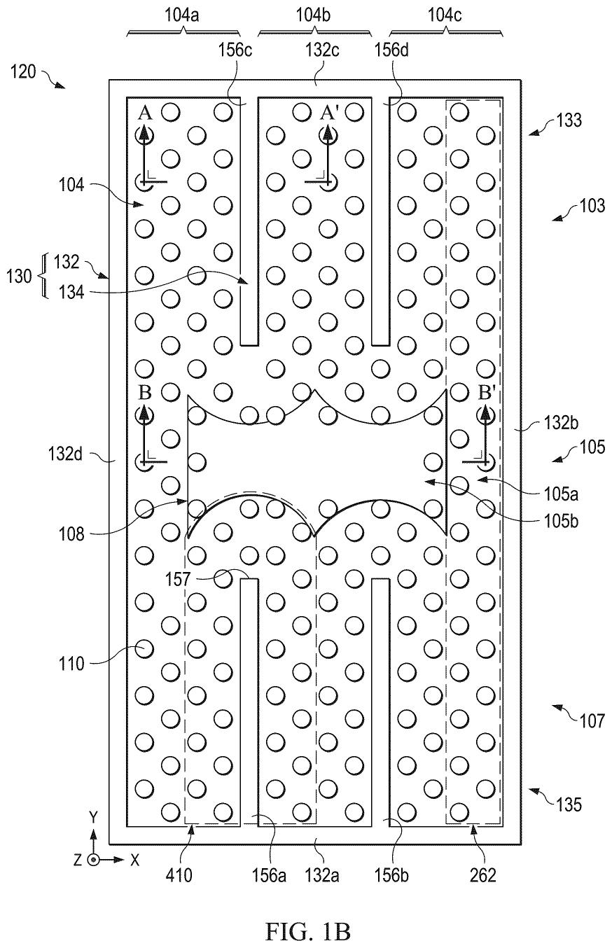

FIG. 1A illustrates a top-down view of an example semiconductor device 100. The 3D memory device 100 can be a memory chip package, a memory die or any portion of a memory die. The 3D memory device 100 can include one or more memory planes 101. In some implementations, as shown in FIG. 1A, the memory plane 101 includes eight memory arrays 120. The memory array 120 can also be referred to as sub memory array tiles (sub-MATs) 120 in this disclosure. The sub-MATs 120 can be arranged laterally along an x direction. Each sub-MAT 120 can include a plurality of memory cells, where each memory cell can be addressed through interconnections such as bit lines and word lines. The bit lines and word lines can be laid out perpendicularly to each other (e.g., in rows and columns, respectively), to form an array of metal lines. The sub-MATs 120 include memory cells. The memory cells form the core area in a memory device, which performs the storage functions.

As illustrated in FIG. 1A, the adjacent sub-MATs, e.g., the first sub-MAT 120a and the second sub-MAT 120b, can be separated by an outer portion 132 of a slit structure. In some implementations, at least some outer portions 132 of slit structures can function as the common source contact (e.g., array common source) for an array of memory strings.

The sub-MATs 120 can be arranged close to each other to achieve higher compacity. Peripheral circuitries (not shown) can be formed surrounding the memory plane 101 and used to control the operations of memory cells in the sub-MATs 120. The peripheral circuitry can include page buffer, word line drivers, input-output (I/O) circuitry, address decoders, row and column address buffers, read/write control logic, row and column decoders, clock generation and control, Error Correction Code (ECC) logic, power management circuitry, any combination thereof, or any other suitable circuitry.

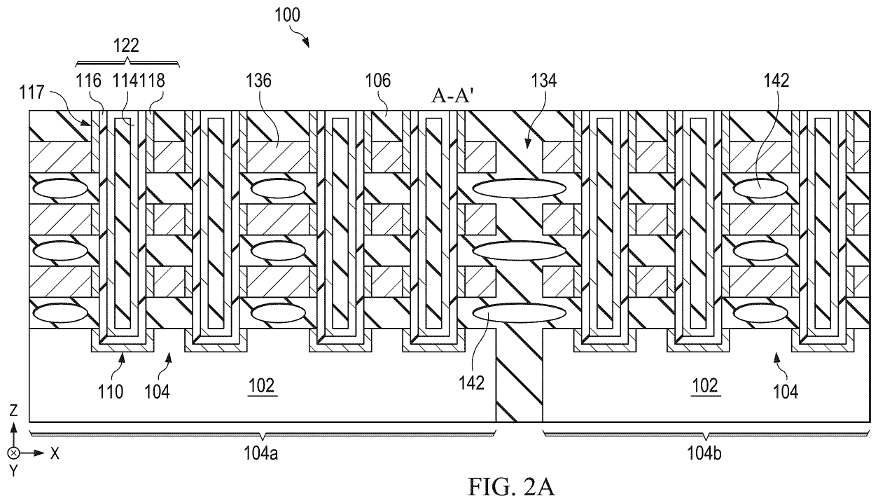

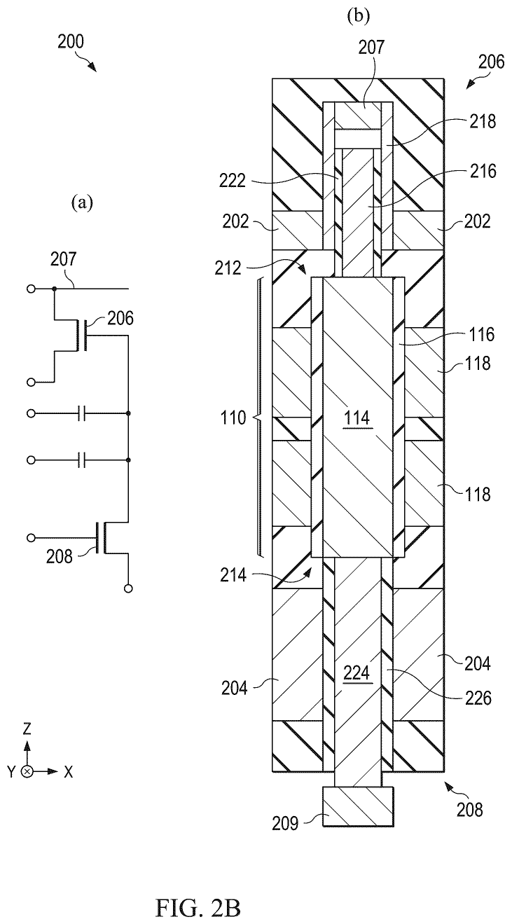

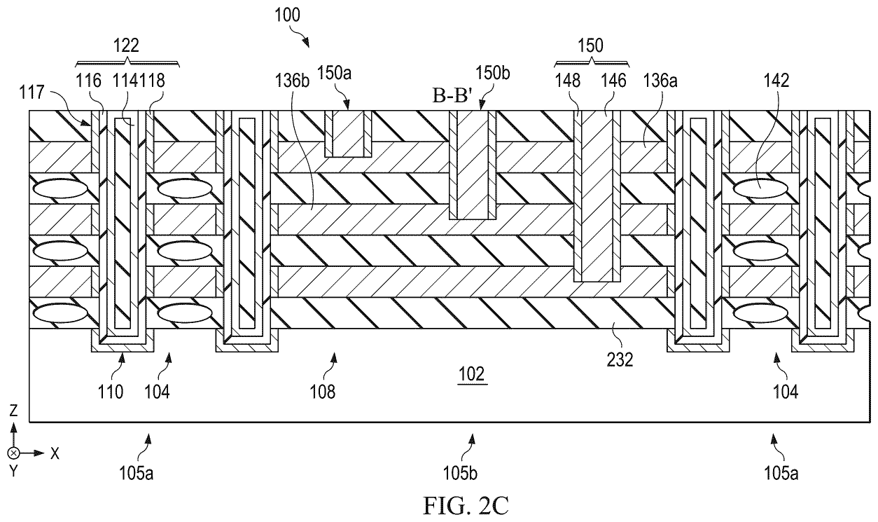

FIG. 1B illustrates an enlarged top-down view of a first implementation of the slit structure 130 in the sub-MAT 120 of the semiconductor device 100. As illustrated in FIG. 1B, in some implementations, the sub-MAT 120 includes a first region 103, a second region 105, and a third region 107 arranged along a lateral direction, e.g., y-direction. The first region 103 and the third region 107 can include a first stack structure 104 and capacitor structures 110 extending vertically through the first stack structure 104, e.g., along a z-direction. The first stack structure 104 and the capacitor structures 110 are configured to form an array of memory strings, each including a plurality of vertically stacked ferroelectric memory cells, as described with further details below in FIGS. 2A-2B. Therefore, the first region 103 and the second region 105 can also be referred to as memory region.

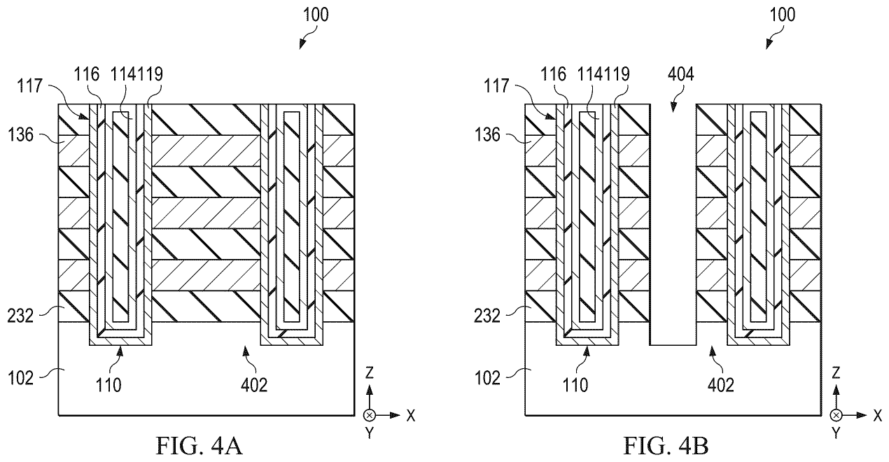

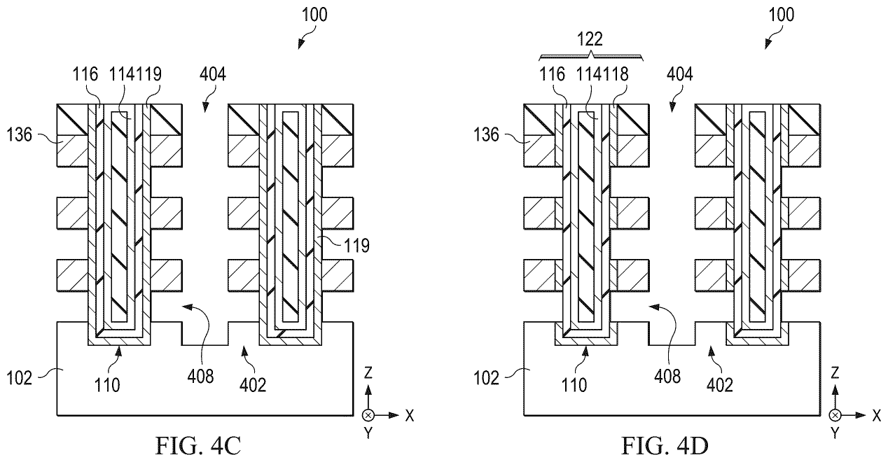

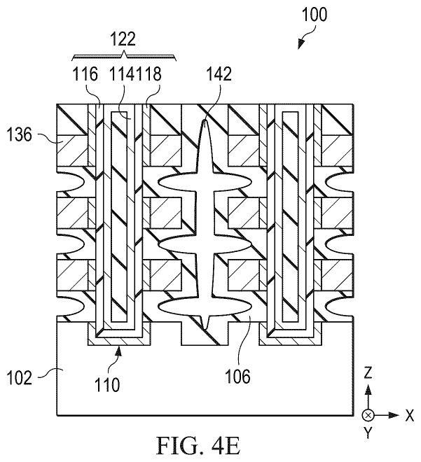

In some implementations, the second region 105 includes a second stack structure 108. The second stack structure 108 can be configured to pad out the plate lines of the ferroelectric memory cells, as described with further details below in FIG. 2C. In some implementations, the second region 105 includes edge areas 105a and a center area 105b. The second stack structure 108 can be located at the center area 105b of the second region 105. The first stack structure 104 can further extend into the edge area 105a of the second region 105, as described with further details below in FIGS. 4A-4E. Therefore, the second stack structure 108 can be laterally surrounded by the first structure 104 as illustrated in FIG. 1B.

The semiconductor device 100 includes a slit structure 130. The slit structure 130 includes an outer portion 132 and an inner portion 134. The outer portion 132 can have an enclosed rectangular shape with four edges, e.g., a first borderline 132a, a second borderline 132b, a third borderline 132c and a fourth borderline 132d. As described in FIG. 1A, the outer portion 132 of the slit structure 130 can be used to separate adjacent sub-MATs 120. Therefore, the outer portion 132 of the slit structure delineates the borderline of each sub-MAT 120.

The inner portion 134 of the slit structure 130 can extend from the outer portions 132 towards the interior of the sub-MAT 120 along a lateral direction, e.g., the y-direction, as shown in FIG. 1B. In some implementations, the inner portion 134 of the slit structure 130 includes one or more liner slit fingers 156. The slit fingers 156 can divide the first stack structure 104 into several memory portions. For example, as shown in FIG. 1B, the inner portion 134 of the slit structure 130 includes two sets of slit fingers. The first set of slit fingers 156a, 156b extends inward into the sub-MAT 120 from the first borderline 132a of the slit structure 130. The second set of slit fingers 156c, 156d extends inward into the sub-MAT 120 from the opposite side, e.g., the third borderline 132c of the slit structure 130. The second set of slit fingers 156c, 156d divide the first stack structure 104 in the first region 103 into three memory portions, 104a, 104b, 104c, which are arranged laterally along the x-direction. In some implementations, the length of the slit fingers 156 is smaller than the length of the borderlines of the slit structure 130 along the same lateral direction. For example, the first slit finger 156a is shorter than the second borderline 132b or the fourth borderline 132d of the slit structure 130 along the y-direction. Therefore, the slit fingers 156 do not partition the sub-MAT 120 into isolated memory portions. Rather, various memory portions, 104a, 104b, 104c, are connected to one another, as shown in FIG. 1B.

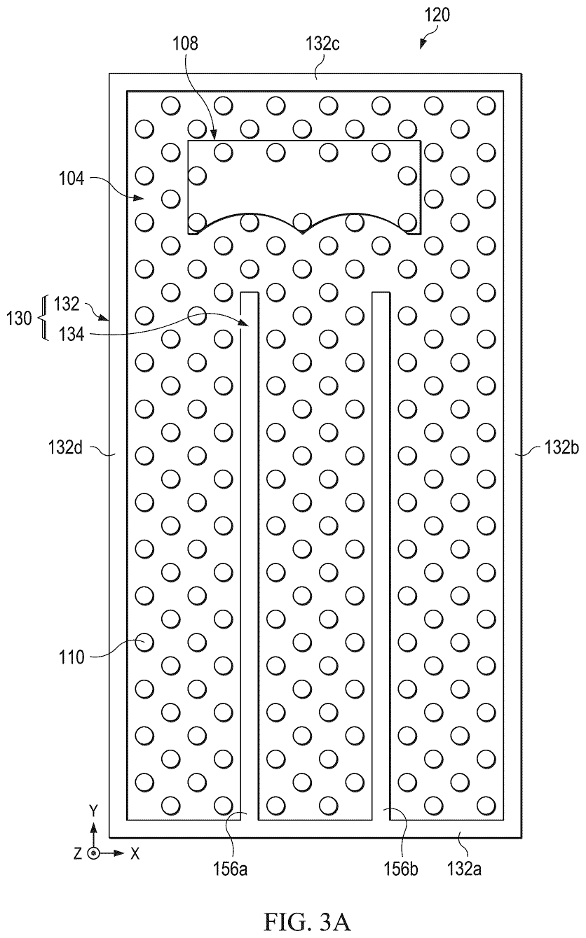

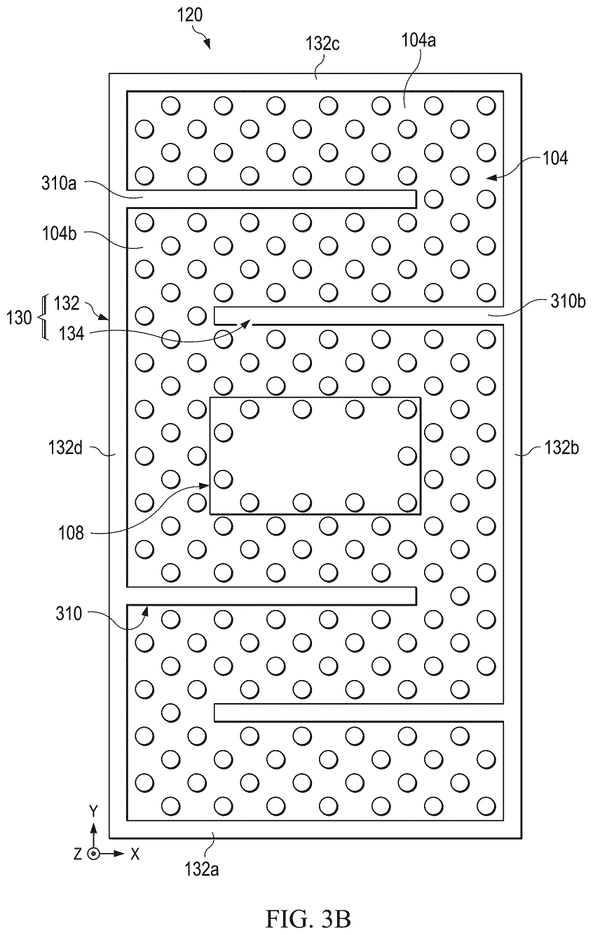

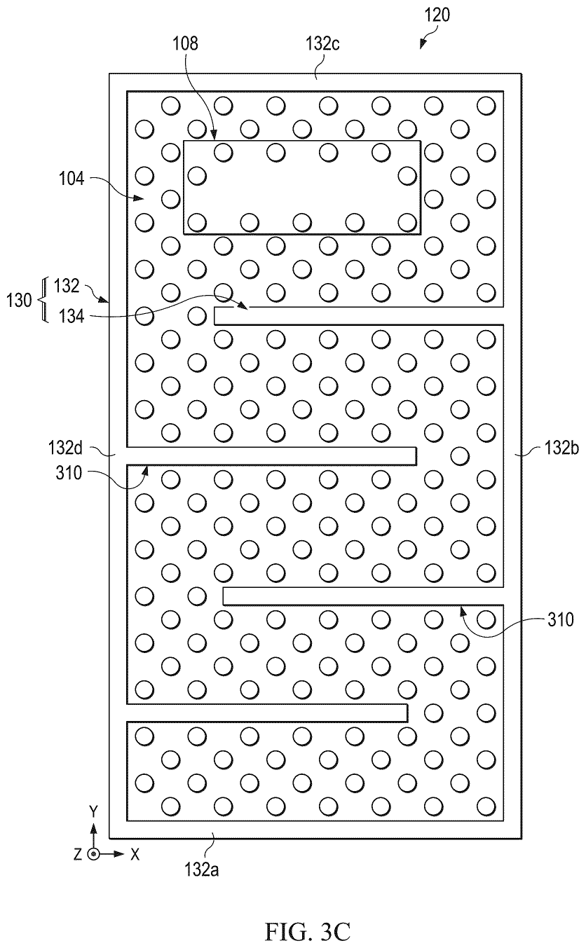

In some implementations, the sub-MAT 120 can include two or more second stack structures 108. The two or more second stack structures 108 can be positioned (not shown) in the first region 103 and the third region 107. The inner portion 134 of the slit structure 130 can be positioned in the second region, e.g., extending inward from the second borderline 132b or the fourth borderline 132d of the slit structure 130 along the x-direction. It is understood that the slit structure can have other suitable configurations, e.g., as described with further details below in FIGS. 3A-3C.

FIG. 2A illustrates a cross-section view of the example first stack structure 104 along the axis A-A′ of FIG. 1B. The first stack structure 104 can be formed on a substrate 102, which is a doped semiconductor layer and can include silicon (e.g., single crystalline silicon), silicon germanium (SiGe), gallium arsenide (GaAs), germanium (Ge), silicon on insulator (SOI), germanium on insulator (GOI), or any other suitable materials. In some implementations, substrate 102 is a thinned substrate (e.g., a semiconductor layer), which was thinned by grinding, etching, chemical mechanical polishing (CMP), or any combination thereof. Substrate 102 of the memory device 100 includes two surfaces (e.g., a top surface and a bottom surface) extending laterally in the x-direction (i.e., the lateral direction). As used herein, whether one component (e.g., a layer or a device) is “on,” “above,” or “below” another component (e.g., a layer or a device) of a 3D memory device (e.g., 3D memory device 100) is determined relative to the substrate of the 3D memory device (e.g., substrate 102) in the z-direction (i.e., the vertical direction) when the substrate is positioned in the lowest plane of the 3D memory device in the z-direction.

In some implementations, 3D memory device 100 is a ferroelectric random-access memory (FeRAM) device in which memory cells are provided in the form of an array of memory strings each extending vertically above substrate 102.

As illustrated in FIG. 2A, the first stack structure 104 has interleaved first conductive layers 136 and first dielectric layers 106. The first conductive layers 136 are also referred to as plate lines 136 in this disclosure. Gate lines 136 can extend laterally coupling a plurality of memory cells. The plate lines 136 can include conductive materials including, but not limited to, tungsten (W), cobalt (Co), copper (Cu), aluminum (Al), doped polysilicon, doped silicon, silicide, or any combination thereof. First dielectric layers 106 can include dielectric materials such as silicon oxide, silicon nitride, silicon oxynitride, or any combination thereof. In some implementations, the first dielectric layers 106 include air gaps surrounded by silicon oxide. Air gaps 142 can be formed during a deposition process, as described with further details below in FIGS. 4A-4E. In some implementations, the first conductive layers 136 of the first stack structure 104 include N+ doped polysilicon.

The semiconductor device 100 further includes capacitor structures 110 which extend through the first stack structure 104 along a first direction, e.g., the z-direction. The capacitor structure 110 includes an inner electrode layer 114, a ferroelectric layer 116 and a plurality of outer electrodes 118. The adjacent outer electrodes 118 are arranged and isolated from each other along the first direction, e.g., the z-direction, by the first dielectric layers 106. Each ferroelectric memory cell 122 can include the inner electrode layer 114, a corresponding outer electrode 118 and the ferroelectric layer 116 in between. The first conductive layers 136 of the first stack structure 104 are in contact with the corresponding outer electrodes 118 of the capacitor structure 110.

As shown in FIG. 2A, the ferroelectric layer 116 can be deposited on a sidewall of a capacitor hole 117. In some implementations, the ferroelectric layer 116 has a thickness in a range between 5 nm and 100 nm. In some implementations, the ferroelectric layer 116 includes a high-k (i.e., high dielectric constant) dielectric material, which can include transitional metal oxides such as hafnium oxide (HfO₂), aluminum oxide (Al₂O₃), Zirconium oxide (ZrO₂), titanium oxide (TiO₂), niobium oxide (Nb₂O₅), tantalum oxide (Ta₂O₅), tungsten oxide (WO₃), molybdenum oxide (MO₃), vanadium oxide (V₂O₃), lanthanum oxide (La₂O₃), and/or any combination thereof.

In some implementations, to improve ferroelectric property, the high-k dielectric material can be doped. For example, the ferroelectric layer 116 can be HfO₂ doped with silicon (Si), (Yttrium) Y, Gadolinium (Gd), Lanthanum (La), Zircomium (Zr) or Aluminum (Al), or any combination thereof. In some implementations, the ferroelectric layer 116 can include Zirconate Titanate (PZT), Strontium Bismuth Tantalate (SrBi₂Ta₂O₉), Barium Titanate (BaTiO₃), PbTiO₃, and BLT (Bi,La)₄Ti₃O₁₂), or any combination thereof. In some implementations, the ferroelectric layer 116 can be disposed by chemical vapor deposition (CVD), for example, metal organic chemical vapor deposition (MOCVD), low pressure chemical vapor deposition (LPCVD), plasma enhanced chemical vapor deposition (PECVD), high-density plasma chemical vapor deposition (HDP-CVD), atomic layer deposition (ALD), sputtering, evaporating, or any combination thereof.

The inner electrode layer 114 can be deposited on a sidewall of the ferroelectric layer 116 in the capacitor hole 117. The outer electrode 118 for each ferroelectric memory cell 122 can be deployed as its control gate. The outer electrodes 118 are connected to corresponding plate lines 136 of the sub-MAT 120. Programming voltages can be applied to the ferroelectric memory cell 122 through the plate line 136 and the outer electrode 118 to alter a polarization state in the ferroelectric layer 116 of the corresponding ferroelectric memory cell 122. The inner electrode layer 114 and/or the outer electrodes 118 can be made of a conductive material, including W, Co, Cu, Al, TiN, TaN, polysilicon, silicide, or any combination thereof. The inner electrode layer 114 and/or the outer electrodes 118 can be deposited by any suitable thin film deposition techniques such as CVD, PVD, ALD, Metal-Organic Chemical Vapor Deposition (MOCVD), sputtering, electroplating, electroless plating, electron-beam evaporation, or any combination thereof.

In some implementations, the capacitor structures 110 can have a cylinder shape (e.g., a pillar shape). In some implementations, capacitor structure 110 can be formed by stacking more than one cylinder structure in multi-stacked memory cells. It is understood that the capacitor structures 110 can have other shapes (e.g., elliptical cylinder or irregular shape).

As illustrated in FIG. 2A, the inner portion 134 of the slit structure 130, e.g., the slit finger 156c (FIG. 1B), extends vertically through the first stack structure 104 into the substrate 102. The inner portion 134 of the slit structure 1306c separates the first stack structure 104 into two memory portions, the first memory portion 104a and the second memory portion 104b (see also FIG. 1B).

In some implementations, slit structure 130 includes air gaps 142 surrounded by silicon oxide, as shown in FIG. 2A. In some implementations, slit structure 130 is a front-side source contact further including (not shown) an inner conductive portion (e.g., including W, polysilicon, and/or TiN) circumscribed by slit spacer. In some implementations, the slit structure 130 includes a slit spacer surrounding the inner conductive portion to separate first conductive layers 136 (plate lines 136) between adjacent memory portions or between adjacent sub-MATs 120. In some implementations, slit structure 130 is an insulating structure that does not include any contact therein (i.e., not functioning as the source contact) and thus, does not introduce parasitic capacitance and leakage current with first conductive layers 136 (plate lines 136).

Although not shown in FIG. 2A, it is understood that the capacitor structures 110 can be coupled to at least one transistor on each of its end. FIG. 2B illustrates a schematic view of an example 2TXC structure 200. 2TXC in this disclosure can refer to a structure with two transistors (2T) and one or more capacitors (XC). Specifically, diagram (a) of FIG. 2B illustrates an equivalent circuit of the 2TXC structure 200, and diagram (b) of FIG. 2B illustrates a cross-section view of the 2TXC structure 200.

As illustrated in diagram (b) of FIG. 2B, in some implementations, each capacitor structure 110 includes at least one transistor at each end, e.g., a first transistor 206 and a second transistor 208. The first transistor 206 is controlled by a gate structure 216. The second transistor 208 is controlled by the lower select gate (LSG) layer 204. The gate structure 216 and the LSG layer 204 can be made of a conductive material including, but not limited to W, Co, Cu, Al, TiN, TaN, polysilicon, silicide, or any combination thereof.

In some implementations, the first transistor 206 is coupled to a first end 212 of the capacitor structure 110, and the second transistor 208 is coupled to a second end 214 of the capacitor structure 110. In some implementations, the first transistor 206 includes a gate structure 216 extending along the first direction, e.g., z direction, and a channel layer 218 is laterally surrounding the gate structure 216. The gate structure 216 is coupled to the inner electrode layer 114 of the capacitor structure 110. One end of the channel layer 218 is coupled to the TSG layer 202, and the other end of the channel layer 218 is coupled to a first bit line, e.g., a read bit line 207. A TSG dielectric layer 222 is positioned between the gate structure 216 and the channel layer 218 in the first transistor 206. This configuration of the first transistor 206 can be referred to as “channel all around” configuration in this disclosure. The gate structure 216, the TSG layer 202, the channel layer 218 and/or the read bit line 207 can be made of a conductive material including, but not limited to, W, Co, Cu, Al, TIN, TaN, SiGe, doped polysilicon, silicide, or any combination thereof. The TSG dielectric layer 222 can be made of dielectric materials, such as silicon oxide, silicon nitride, or high-k dielectrics including, but not limited to, Al₂O₃, HfO₂, Ta₂O₅, ZrO₂, TiO₂, or any combination thereof.

In some implementations, the second transistor 208 includes a channel structure 224 extending along the first direction, e.g., the z direction. One end of the channel structure 224 is coupled to the inner electrode layer 114 of the capacitor structure 110. The other end of the channel structure 224 is coupled to a second bit line, e.g., a write bit line 209. The channel structure 224 can be made of doped polysilicon. The channel structure 224 is surrounded by the LSG layer 204 with the LSG dielectric layer 226 positioned between them. This configuration of the second transistor 208 can be referred to as “gate all around” configuration in this disclosure. The channel structure 224 and/or the write bit line 209 can be made of a conductive material including, but not limited to, W, Co, Cu, Al, TIN, TaN, SiGe, doped polysilicon, silicide, or any combination thereof. The LSG dielectric layer 226 can be made of dielectric materials, such as silicon oxide, silicon nitride, or high-k dielectrics including, but not limited to, Al₂O₃, HfO₂, Ta₂O₅, ZrO₂, TiO₂, or any combination thereof.

Referring to diagram (a) of FIG. 2B, in some implementations, the first transistor 206 is deployed for read operations, and the second transistor 208 is deployed for write operations. In some implementations, the second transistor 208 can be controlled by a programming voltage applied to the LSG 204. If the second transistor 208 is turned on under the programming voltage, it allows the signal to flow into the capacitor structure 110 for programing the ferroelectric memory cells 122. In addition, as the inner electrode layer 114 of the capacitor structure 110 is connected to the gate structure 216 of the first transistor 206, the first transistor 206 can be controlled by the stored data of the capacitor structure 110. Therefore, the first transistor 206 can be used to read the ferroelectric memory cells 122. This configuration can achieve non-destructive read operations without the need for rewrite operations.

FIG. 2C illustrates a cross-section view of the second stack structure 108 along B-B′ axis of FIG. 1B. As noted in FIG. 1B, in some implementations, the second stack structure 108 is laterally surrounded by the first stack structure 104. In some implementations, the second stack structure 108 includes the first conductive layers 136 interleaved with second dielectric layers 232. The second dielectric layers 232 can include dielectric materials including, but not limited to, silicon oxide, silicon nitride, silicon oxynitride, or any combination thereof. The second dielectric layers 232 can be deposited using one or more thin film deposition techniques, including, but not limited to, chemical vapor deposition (CVD), physical vapor deposition (PVD), atomic layer deposition (ALD), sputtering, or any combination thereof.

In some implementations, the semiconductor device 100 includes conductive structures 150 extending into the second stack structure 108 at different depths. Each conductive structure 150 is connected to a respective one of the first conductive layers 136 (plate lines 136). Therefore, the conductive structures 150 can be electrically connected to plate lines 136 at different levels to pad out plate lines 136. For example, the first conductive structure 150a is connected to the first plate line 136a, while the second conductive structure 150b is connected to the second plate line 136b. The first plate line 136a and the second plate line 136b are used to control corresponding ferroelectric memory cells 122 via outer electrodes 118.

In some implementations, the conductive structures 150 include a conductive material 146 surrounded by spacers 148. The spacer 148 can be used to isolating the conductive material 146 from surrounding plate lines 136. The conductive material 146 can include, without limitation to, W, Co, Cu, Al, TiN, TaN, polysilicon, or any combination thereof. The material of the spacers 148 can include, without limitation to, silicon oxide, silicon nitride, silicon oxynitride, or any combination thereof. In some implementations, the conductive material 146 includes TiN and W, and the material of the spacer includes silicon oxide.

FIGS. 3A-3C illustrates additional implementations of the slit structure 130 in the sub-MAT 120 of the semiconductor device 100. As described above, in some implementations, each sub-MAT 120 has the first stack structure 104, the capacitor structures 110, the inner portion 134 of the slit structure 130 and the second stack structure 108. As the outer portion 132 of the slit structure 130 defines boundaries between neighboring sub-MATs 120, it can be utilized by multiple adjacent sub-MATs 120. The first stack structure 104 and the capacitor structures 110 can form one or more memory strings each extending perpendicularly to the substrate 102. In each memory string, ferroelectric memory cells 122 are vertically stacked in one or more capacitor structures 110. The second stack structure 108 can be utilized for padding out plate lines 136 of the ferroelectric memory cells 122.

In a second implementation illustrated in FIG. 3A, unlike the first implementation shown in FIG. 1B where the slit structure 130 includes two sets of inner slit fingers 156 at two ends of the sub-MAT 120, the slit structure 130 can include one set of inner slit fingers 156 which extend inward into the sub-MAT 120, e.g., from the first borderline 132a of the slit structure 130. The second stack structure 108 can be formed closer to the opposite side of the sub-MAT 120, e.g., adjacent to the third borderline 132c of the slit structure 130. The remaining region of the sub-MAT can form the memory regions with the first stack structure 104 and the capacitor structures 110.

In a third implementation illustrated in FIG. 3B, in contrast to the first implementation shown in FIG. 1B where the slit fingers 156 extend inward along the length of the sub-MAT 120, the inner portion 134 of the slit structures 130 can include two or more interlocking slit fingers 310 extending inward along the width of the sub-MAT 120. The interlocking slit fingers 310 can protrude towards one another. For example, the first slit finger 310a extends inward from the fourth borderline 132d, while the second slit finger 310b extends inward from the second borderline 132b towards the first slit finger 310a, as shown in FIG. 3B. In some implementations, the length of the slit fingers 310 along the x-direction is smaller than that of the outer portion 132 of the slit structure 130 such that different memory portions are connected to one another. For example, the first memory portion 104a and the second memory portion 104b are connected to each other. These memory portions 104a, 104b are further connected to the second stack structure 108 through first conductive layers 136 or plate lines 136 for pad-out/fan-out via the conductive structures 150 (FIG. 2C).

In a fourth implementation illustrated in FIG. 3C, unlike the second implementation shown in FIG. 3A where the slit fingers 156 are extending along the y-direction, the inner portion 134 of the slit structures 130 can include two or more interlocking slit fingers 310 extending along the x-direction, similar to that of the third implementation in FIG. 3B.

FIGS. 4A-4E illustrate cross-section views of the semiconductor device 100 along A-A′ axis of the FIG. 1B at various stages of a fabrication process. As illustrated in FIG. 4A, a stack structure 402 is formed on the substrate 102 which includes first conductive layers 136 interleaved with the second dielectric layers 232. Second dielectric layers 232 can include dielectric materials including, but not limited to, silicon oxide, silicon nitride, silicon oxynitride, or any combination thereof. The first conductive layers 136 can be N+ doped polysilicon.

Capacitor structures 110 are formed which extend through the stack structure along the z direction. In some implementations, the capacitor structures 110 have a cylinder shape, as shown. An inner electrode layer 114, a ferroelectric layer 116, and an outer electrode layer 119 can be deposited on the sidewall of capacitor holes 117. The outer electrode layer 119 can be etched into multiple outer electrodes 118 at a later stage of the process, as described with further details below in FIG. 4D.

As illustrated in FIG. 4B, a slit structure trench 404 is formed which extends through the stack structure 402. In some implementations, the slit structure trench 404 is partially etched into the substrate 102. The slit structure trench 404 can be filled with a dielectric material to form the slit structure 130 at a later stage of the process, e.g., as illustrated in FIG. 4E. Therefore, the slit structure trench 404 can have a layout or configuration identical or substantially similar to the slit structures 130 as illustrated in FIGS. 1B and 3A-3C. The slit structure trench 404 can include slit finger trenches, which resembles the configuration of slit fingers 156, 310 in FIGS. 1B and 3A-3C.

As illustrated in FIG. 4C, the second dielectric layers 232 in the stack structure 402 are partially removed by a wet etch and/or dry etch process through the slit structure trench 404. After the removal of the second dielectric layers 232, a plurality of openings 408 can be formed between adjacent first conductive layers 136. Consequently, part of the outer electrode layer 119 is exposed.

In some implementations, the etching process to partially remove the second dielectric layers 232 is an isotropic etch such that the second dielectric layers 232 can be removed uniformly from all directions surrounding the slit structure trench 404. In some implementations, the etched region has a roughly circle shape at an end or a tip of each slit finger trench. For example, referring back to FIG. 1B, when etchants are introduced into the trench of the slit finger 156a, because of isotropic etch, a window-shaped etched region 410 can be formed. More specifically, along the length of the slit finger trench, e.g., along the y-direction, the etching process can create a rectangular region as the etch progresses laterally along both positive x-direction and negative x-direction. For the etchant entering from the end 157 of the slit finger trench, it interacts with the material on all sides, resulting in a roughly circular shape centered at the end of the slit finger trench. As a result, the window-shaped etched region 410 can be formed. Similarly, other slit finger trenches can also form identical or similar window-shaped etched region as illustrated in FIG. 1B.

The slit structure trenches 404 include four borderline trenches, which resemble the configuration or layout of the outer portion 132 of the slit structure 130, as illustrated in FIG. 1B. Each borderline trench can be used to create rectangular etched region adjacent to it. For instance, after introducing the etchant through the trench of the second borderline 132b, the etched region 262 can be formed. This etched region 262 can extend through all three regions in the sub-MAT 120 alongside the second borderline 132b, e.g., through the first region 103, the second region 105 and the third region 107 along y-direction. Therefore, in the edge area 105a of the second region 105, the second dielectric layers 232 can be removed, allowing for the formation of the first stack structure 104 in that area during later stages of the process.

As illustrated in FIG. 1B, since the inner portion of the slit structure trench 404 doesn't extend into the second region 105, the second region 105 can have some remaining portions of the second dielectric layers 232 in its center area 105b. The dimension of the remaining second dielectric layers 232 can be controlled by etching parameters, e.g., etch time and/or etch rate. For example, the etching time can be long enough to remove all the second dielectric layers 232 in the first region 103 and the third region 107 but short enough to leave some portion of the second dielectric layers 232 intact in the center area 105b of the second region 105. The stack structure 402 with the remaining second dielectric layers 232 can form the second stack structure 108.

Although the illustration of the etching process is described with reference to the first implementation of the slit structure 130 in FIG. 1B, the same etching process is applicable to any of the implementations of the slit structure 130 shown in FIGS. 3A-3C or other suitable arrangements with an inner portion of the slit structure extending inward into the sub-MAT 120.

Referring back to FIG. 4C, the etching of the second dielectric layers 232 can involve one or more dry etching and/or wet etching techniques, including, but not limited to, reactive ion etching (RIE), plasma etching, hydrofluoric acid (HF) etching, sputtering etching, KOH Etching (Potassium Hydroxide), TMAH Etching (Tetramethylammonium Hydroxide), Buffered Oxide Etchant (BOE), Piranha Solution (H2SO4/H2O2), or any combination thereof.

As noted above, the inner portion of the slit structure trenches 404 can increase the contact area between etchants and the second dielectric layers 232, enhancing uniformity of the etching process inside the sub-MAT 120. Increased contact area can also reduce the required etching duration, leading to improved efficiency of the etching process. In addition, some portions of the second dielectric layers 232 can be retained in certain area of the sub-MAT 120 after etching, e.g., the second region 105 of FIG. 1B, for plate lines pad-out. This eases the need for extra process steps to separate the memory region (e.g., the first stack structure) and plate lines pad-out regions (e.g., the second stack structure), hence enhances integration of the memory system.

As illustrated in FIG. 4D, the exposed part of the outer electrode layer 119 is etched, forming a plurality of outer electrodes 118 separated from one another along z direction. The etching can involve selective etching such that only the material for outer electrodes 118 is removed while leaving the first conductive layer 136 intact. In some implementations, the outer electrodes 118 include TiN, while the first conductive layers 136 include doped polysilicon. In some implementations, the etching process includes, but not limited to, reactive ion etching (RIE), plasma etching, hydrofluoric acid (HF) etching, sputtering etching, KOH Etching (Potassium Hydroxide), TMAH Etching (Tetramethylammonium Hydroxide),

As illustrated in FIG. 4E, the openings 408 are at least partially filed with a dielectric material to form the first dielectric layers 106, and the slit structure trench 404 are also partially filled with the dielectric material to form the slit structures 130. In some implementations, the dielectric material includes silicon oxide. In some implementations, air gaps 142 are formed in the openings 408 and slit structure trenches 404 due to factors, such as, high-aspect ratios, or deposition rate. In some implementations, both the openings 408 and the slit structure trenches 404 are filled with the dielectric material simultaneously at the same process steps.

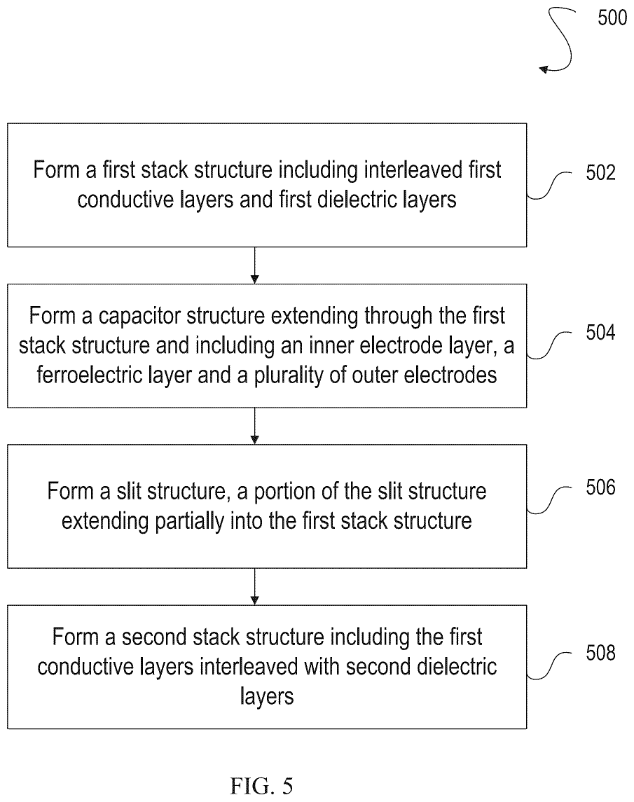

FIG. 5 is a flow diagram of an example process 500 to form the semiconductor device 100. At step 502, a first stack structure is formed which includes interleaved first conductive layers and first dielectric layers. The first stack structure can be, e.g., the first stack structure 104 of FIGS. 1B-4E. The first conductive layers can be, e.g., the first conductive layers 136 of FIGS. 2A-4E. The first dielectric layers can be, e.g., the first dielectric layers 106 of FIGS. 2A-4E.

At step 504, a capacitor structure is formed which extends through the first stack structure along a first direction. The capacitor structure includes an inner electrode layer, a ferroelectric layer and a plurality of outer electrodes. Adjacent outer electrodes of the plurality of outer electrodes are arranged and isolated from each other along the first direction. The capacitor structure can be, e.g., the capacitor structure 110 of FIGS. 1B-4E. The inner electrode layer can be, e.g., the inner electrode layer 114 of FIGS. 2A-2C and 4A-4E. The ferroelectric layer can be, e.g., the ferroelectric layer 116 of FIGS. 2A-2C and 4A-4E. The outer electrodes can be, e.g., the outer electrodes 118 of FIGS. 2A-2C and 4D-4E. The first direction can be, e.g., the z-direction of FIGS. 2A-2C and 4A-4E.

At step 506, a slit structure is formed. A portion of the slit structure extends partially into the first stack structure. The slit structure can be, e.g., any one of the slit structures 130 of FIGS. 1A-2A and 3A-4E. The portion of the slit structure can be, e.g., the inner portion 134 of the slit structure 130 of FIGS. 1B-2A, 3A-3C and 4E. In some implementations, the slit structure 130 also includes an outer portion 132 to separate neighboring sub-MATs 120, as described in FIGS. 1A-1B and 3A-3C.

At step 508, a second stack structure is formed which includes the first conductive layers interleaved with second dielectric layers. The second stack structure is adjacent to the first stack structure. The second stack structure can be surrounded the first stack structure in all lateral directions. The second stack structure can be, e.g., the second stack structure 108 of FIGS. 1B and 2C-3C. The second dielectric layers can be, e.g., the second dielectric layer 232 of FIGS. 2C and 4A-4B.

In some implementations, forming the second stack structure includes forming the inner electrode layer, the ferroelectric layer and an outer electrode layer in capacitor holes, as illustrated in FIG. 4A. The outer electrode layer can be, e.g., the outer electrode layer 119 of FIGS. 4A-4B. The capacitor holes can be, e.g., the capacitor holes 117 of FIGS. 2A and 4A-4E. A stack structure is formed which includes the first conductive layers interleaved with the second dielectric layers. The stack structure can be, e.g., the stack structure 402 of FIGS. 4A-4B. A slit structure trench is formed which extends through the stack structure along the first direction. The slit structure trench can be, e.g., the slit structure trench 404 of FIGS. 4B-4D. As noted above, the slit structure trench 404 can have identical layout or configuration as any one of the slit structures 130 of FIGS. 1B and 3A-3C. A part of the second dielectric layers is etched through the slit structure trench to form openings and expose a part of the outer electrode layer. The openings can be, e.g., the openings 408 of FIGS. 4C-4D.

In some implementations, as illustrated in FIGS. 4D and 4E, forming the first stack structure includes etching the exposed part of the outer electrode layer to form the plurality of outer electrodes; and at least partially filling the openings with a dielectric material to form the first dielectric layers.

In some implementations, forming the slit structure includes at least partially filling the slit structure trench with the dielectric material, as illustrated in FIG. 4E.

In some implementations, the process 500 includes forming conductive structures extending into the second stack structure at different depths. Each of the conductive structures is electronically connected to a respective one of the first conductive layers. The conductive structures can be, e.g., the conductive structures 150 of FIG. 2C.

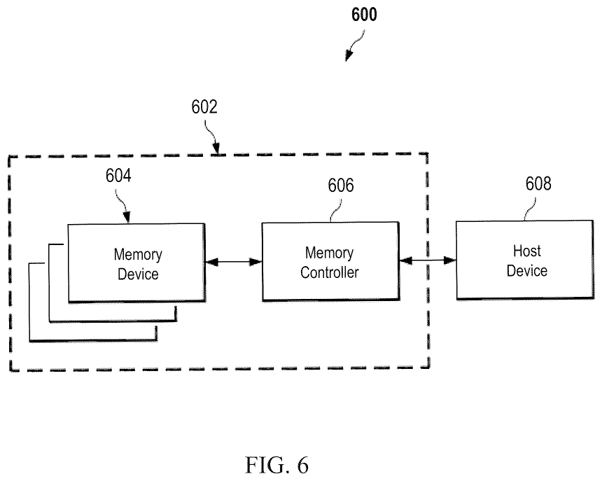

FIG. 6 illustrates a block diagram of a system 600 having one or more semiconductor device 100s (e.g., memory devices), according to one or more implementations of the present disclosure. The system 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, the system 600 can include a host device 608 and a memory system 602 having one or more 3D memory devices 604 and a memory controller 606. Host device 608 can include a processor of an electronic device, such as a central processing unit (CPU), or a system-on-chip (SoC), such as an application processor (AP). Host device 608 can be configured to send or receive data to or from the one or more 3D memory devices 604.

A 3D memory device 604 can be any 3D memory device disclosed herein, such as the 3D semiconductor device 100 of FIG. 1A, or a part of the 3D semiconductor device 100 (e.g., the sub-MAT 120 of FIGS. 1B and 3A-3C, the 2TXC structure 200 of FIG. 2B, or the part of the 3D semiconductor device 100 of FIGS. 2A and 2C), or a structure at an intermediate fabrication process of the 3D semiconductor device 100 of FIGS. 4A-4E.

In some implementations, a 3D memory device 604 includes a NAND Flash memory. Memory controller 606 (a.k.a., a controller circuit) is coupled to 3D memory device 604 and host device 608. Consistent with implementations of the present disclosure, 3D memory device 604 can include a plurality of conductive interconnections through a cover layer that are in contact with conductive pads in a conductive pad layer, and memory controller 606 can be coupled to 3D memory device 604 through at least one of the plurality of conductive interconnections. Memory controller 606 is configured to control 3D memory device 604. For example, memory controller 606 may be configured to operate a plurality of capacitor structures 110 via word lines. Memory controller 606 can manage data stored in 3D memory device 604 and communicate with host device 608.

In some implementations, memory controller 606 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 606 can be configured to control operations of 3D memory device 604, such as read, erase, and program (or write) operations. Memory controller 606 can also be configured to manage various functions with respect to the data stored or to be stored in 3D memory device 604 including, but not limited to bad-block management, garbage collection, logical-to-physical address conversion, wear leveling, etc. In some implementations, memory controller 606 is further configured to process error correction codes (ECCs) with respect to the data read from or written to 3D memory device 604. Any other suitable functions may be performed by memory controller 606 as well, for example, formatting 3D memory device 604.

Memory controller 606 can communicate with an external device (e.g., host device 608) according to a particular communication protocol. For example, memory controller 606 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 606 and one or more 3D memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 6, memory controller 606 and a single 3D memory device 604 may be integrated into a memory card 602. Memory card 602 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate 102, a random or serial access memory device, or a combination of one or more of them. A computer storage medium is not a propagated signal.

It is noted that references in the present disclosure to “one implementation,” “an implementation,” “an example implementation,” “some implementations,” “some implementations,” “one implementation,” “an implementation,” “an example implementation,” etc., indicate that the implementation described can include a particular feature, structure, or characteristic, but every implementation can not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically no N+conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., +−.10%, +−.20%, or +−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a first stack structure comprising interleaved first conductive layers and first dielectric layers,
a capacitor structure extending through the first stack structure along a first direction, the capacitor structure comprising an inner electrode layer, a ferroelectric layer and a plurality of outer electrodes, adjacent outer electrodes of the plurality of outer electrodes being arranged and isolated from each other along the first direction;
a slit structure, wherein a portion of the slit structure extends partially into the first stack structure along a second direction perpendicular to the first direction; and
a second stack structure adjacent to the first stack structure, wherein the second stack structure and the first stack structure are arranged along the second direction or a third direction perpendicular to the first direction and the second direction, wherein the second stack structure comprises the first conductive layers interleaved with second dielectric layers.

2. The semiconductor device of claim 1, further comprising: a first transistor coupled to a first end of the capacitor structure, and a second transistor coupled to a second end of the capacitor structure.

3. The semiconductor device of claim 2, wherein the first transistor comprises a gate structure extending along the first direction and a channel layer laterally surrounding the gate structure, the gate structure being coupled to the inner electrode layer of the capacitor structure, a first end of the channel layer being coupled to a select gate layer, a second end of the channel layer being coupled to a first bit line, and
wherein the second transistor comprises a channel structure extending along the first direction, a first end of the channel structure being coupled to the inner electrode layer of the capacitor structure, a second end of the channel structure being coupled to a second bit line.

4. The semiconductor device of claim 1, further comprising:
conductive structures extending into the second stack structure at different depths and each being connected to a respective one of the first conductive layers.

5. The semiconductor device of claim 1, wherein each of the first conductive layers comprises doped polysilicon coupled to a corresponding one of the outer electrodes of the capacitor structure.

6. The semiconductor device of claim 1, wherein the semiconductor device comprises a plurality of memory arrays each having the first stack structure, the capacitor structure, the portion of the slit structure and the second stack structure.

7. The semiconductor device of claim 6, wherein the portion of the slit structure is an inner portion of the slit structure, and wherein the slit structure further comprises an outer portion configured to isolate adjacent memory arrays of the plurality of memory arrays.

8. The semiconductor device of claim 1, wherein the semiconductor device comprises a first region, a second region, and a third region arranged along the second direction, wherein the first stack structure is located in the first region and the third region, and wherein the second stack structure is located in the second region.

9. The semiconductor device of claim 8, wherein the second region comprises an edge area and a center area, the second stack structure is at the center area, and the first stack structure extends into the edge area of the second region.

10. The semiconductor device of claim 1, wherein the portion of the slit structure comprises one or more liner slit fingers.

11. The semiconductor device of claim 1, wherein the first dielectric layers comprise air gaps surrounded by silicon oxide, and the second dielectric layers comprise silicon oxide.

12. A semiconductor device, comprising:
a first stack structure comprising interleaved first conductive layers and first dielectric layers;
a second stack structure laterally surrounded by the first stack structure, the second stack structure comprising the first conductive layers interleaved with second dielectric layers; and
a plurality of conductive structures extending into the second stack structure at different depths along a first direction, each of the plurality of conductive structures being connected to a respective one of the first conductive layers.

13. The semiconductor device of claim 12, wherein the first dielectric layers comprise air gaps.

14. The semiconductor device of claim 12, wherein the plurality of conductive structures comprise a conductive material surrounded by spacers.

15. The semiconductor device of claim 12, further comprising a capacitor structure extending through the first stack structure along the first direction, the capacitor structure comprising an inner electrode layer, a ferroelectric layer and a plurality of outer electrodes, adjacent outer electrodes of the plurality of outer electrodes being arranged and isolated from each other along the first direction.

16. The semiconductor device of claim 15, wherein each of the first conductive layers comprises doped polysilicon being in contact with a corresponding one of the outer electrodes of the capacitor structure.

17. A method to form a semiconductor device, comprising:
forming a first stack structure comprising interleaved first conductive layers and first dielectric layers;
forming a capacitor structure extending through the first stack structure along a first direction and comprising an inner electrode layer, a ferroelectric layer and a plurality of outer electrodes, adjacent outer electrodes of the plurality of outer electrodes being arranged and isolated from each other along the first direction;
forming a slit structure, wherein a portion of the slit structure extends partially into the first stack structure; and
forming a second stack structure comprising the first conductive layers interleaved with second dielectric layers, the second stack structure adjacent to the first stack structure.

18. The method of claim 17, wherein forming the second stack structure comprises:
forming the inner electrode layer, the ferroelectric layer and an outer electrode layer in capacitor holes;
forming a stack structure comprising the first conductive layers interleaved with the second dielectric layers;
forming a slit structure trench extending through the stack structure along the first direction; and
etching a part of the second dielectric layers through the slit structure trench to form openings and expose a part of the outer electrode layer.

19. The method of claim 18, wherein forming the first stack structure comprises:
etching the exposed part of the outer electrode layer to form the plurality of outer electrodes; and
at least partially filling the openings with a dielectric material to form the first dielectric layers.

20. The method of claim 17, comprising: forming conductive structures extending into the second stack structure at different depths, each of the conductive structures being electronically connected to a respective one of the first conductive layers.
